(19) United States
(12) Patent Application Publication
(10) Pub. No.: US 2025/0059440 A1
(43) Pub. Date: Feb. 20, 2025

(54) SYNTHESIS OF CHALCOGENIDE PEROVSKITE NANOPARTICLES

(71) Applicant: UNIVERSITY OF FLORIDA RESEARCH FOUNDATION, INCORPORATED, Gainesville, FL (US)

(72) Inventors: Charles J. HAGES, Gainesville, FL (US); Alexander D. JESS, Gainesville, FL (US); Ruiquan YANG, Gainesville, FL (US)

(21) Appl. No.: 18/804,551

(22) Filed: Aug. 14, 2024

Related U.S. Application Data
(60) Provisional application No. 63/543,188, filed on Oct. 9, 2023.
(60) Provisional application No. 63/532,576, filed on Aug. 14, 2023.

(51) Int. Cl. C09K 11/67; B82Y 20/00; B82Y 40/00; C01G 25/00; H10K 30/50

(52) U.S. Cl. CPC C09K 11/673; C01G 25/006; B82Y 20/00; B82Y 40/00; C01P 2002/72; C01P 2002/82; C01P 2002/84; C01P 2004/04; C01P 2004/64; C01P 2006/60; H10K 30/50

(57) ABSTRACT

Disclosed herein are methods to synthesize perovskite nanoparticles in solution and at a relatively low temperature (110-300 C). This synthesis of low-temperature, solution-based chalcogenide perovskites were shown to produce materials with excellent optoelectronic properties. Furthermore, disclosed is a technique to stabilize the desired phase of these perovskites (particularly those phases which can not be fabricated in existing techniques). In addition, the material of the composition BaZrS3 (barium zirconium sulfide) has been synthesized in the perovskite crystal structure as nanoparticles for the first time.

### STATEMENT OF GOVERNMENT SUPPORT

This invention was made with government support under Grant Number 2044859, awarded by the National Science Foundation. The government has certain rights in the invention.

### BACKGROUND

Chalcogenide perovskites are an emerging field in new semiconductor materials, particularly for photovoltaics. Most materials have not been made in this family. Of those made, the vast majority of reported syntheses require temperatures around 1000 C and reaction times on the order of days to weeks (generally using solid reaction techniques). This limits their use and research in this field. We have invented a technique to synthesize chalcogenide perovskite nanoparticles.

New energy saving requirements for solid-state lighting (SSL) systems has made it increasingly important to be able to tailor the spectra of those SSL systems. A need exists for tailoring the spectra of SSL systems according to the demands of different applications to maximize the effectiveness of the lighting. A need exists for SSL systems that can ensure the presence of necessary components of the spectrum for specific lighting requirements while at the same time reducing or omitting unnecessary or even damaging portions of the spectrum.

Cost is always a factor when developing such displays and SSL systems. A need, therefore, exists not only for improved products but also for improved manufacturing techniques.

The discussion of shortcomings and needs existing in the field prior to the present invention is in no way an admission that such shortcomings and needs were recognized by those skilled in the art prior to the present disclosure.

### BRIEF SUMMARY

Disclosed herein are methods to synthesize perovskite nanoparticles in solution and at a relatively low temperature (110-300 C). This is the first reported synthesis of low-temperature, solution-based chalcogenide perovskites. It has also been found that the produced chalcogenide perovskites have excellent optoelectronic properties. Furthermore, provided is a technique to stabilize the desired phase of these perovskites (particularly those phases which can not be fabricated in existing techniques). In addition, the material of the composition BaZrS3 (barium zirconium sulfide) has been synthesized in the perovskite crystal structure as nanoparticles for the first time.

These particles may be utilized as is for various optoelectronic applications or may undergo further processing to produce high-performance films and coatings. These and other features, aspects, and advantages of various embodiments will become better understood with reference to the following description, figures, and claims.

### BRIEF DESCRIPTION OF DRAWINGS

FIG. 1. XRD pattern of the BaZrS3 nanoparticles following an 18 h reaction. The reference pattern from Clearfield16 is shown for comparison. Impurity peaks are labeled with a and b. The insets show the synthesized nanoparticles as a stable dispersion in toluene and the crystal structure of distorted perovskite BaZrS3. It should be understood that the various embodiments are not limited to the examples illustrated in the figures.

FIGS. 2A-C. FIG. 2A Bright-field TEM image of the BaZrS3 nanoparticles following an 18 h reaction. FIG. 2B HRTEM image of a BaZrS3 crystal domain showing (002) and (121) plane fringes; the d-spacings and dihedral angle are labeled. The inset shows respective planes in a crystal cell marked with green lines in the same orientation of the crystal domain. FIG. 2C HRTEM image of an individual nanoparticle showing multiple crystal domains; (220) plane fringes are shown with the corresponding d-spacing labeled.

FIGS. 3A-B. FIG. 3A Absorbance (as a Tauc plot) and steady-state PL spectra for various reaction times; the dashed lines indicate the PL peak position and linear fits extrapolated to the band gap (intercept) for the Tauc plot. FIG. 3B Normalized TRPL from different reaction times: blue, 0.5 h; orange, 1 h; green, 3 h; red, 18 h.

FIGS. 4A-B. XRD patterns of FIG. 4A BaZrS3 nanoparticles (NPs) and FIG. 4B initial precipitates from different reaction times. Reference data is taken from Clearfield4 for BaZrS3.

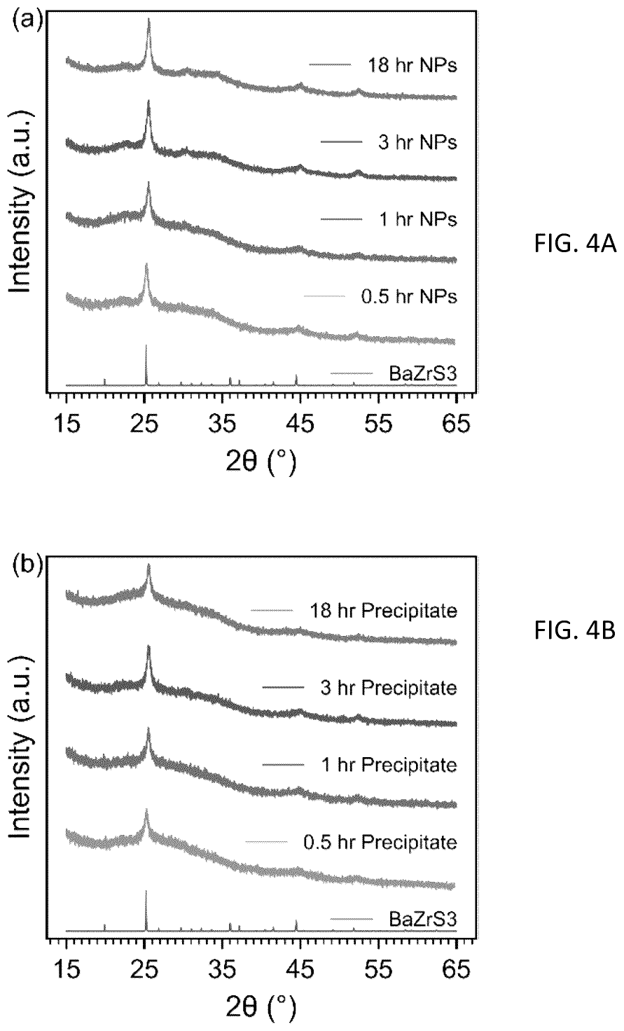

FIG. 5. Raman spectrum of BaZrS3 nanoparticles from the 18 hr reaction. Reference data is taken from Wei et al.⁵

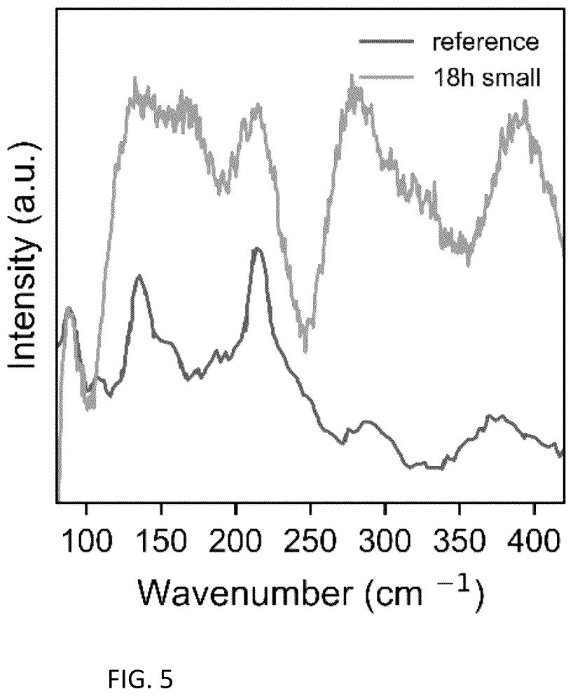

FIGS. 6A-C. Bright-field TEM image of FIG. 6A initial precipitate from the 18 hr reaction, FIG. 6B BaZrS3 nanoparticles from the 3 hr reaction and FIG. 6C initial precipitate from the 3 hr reaction.

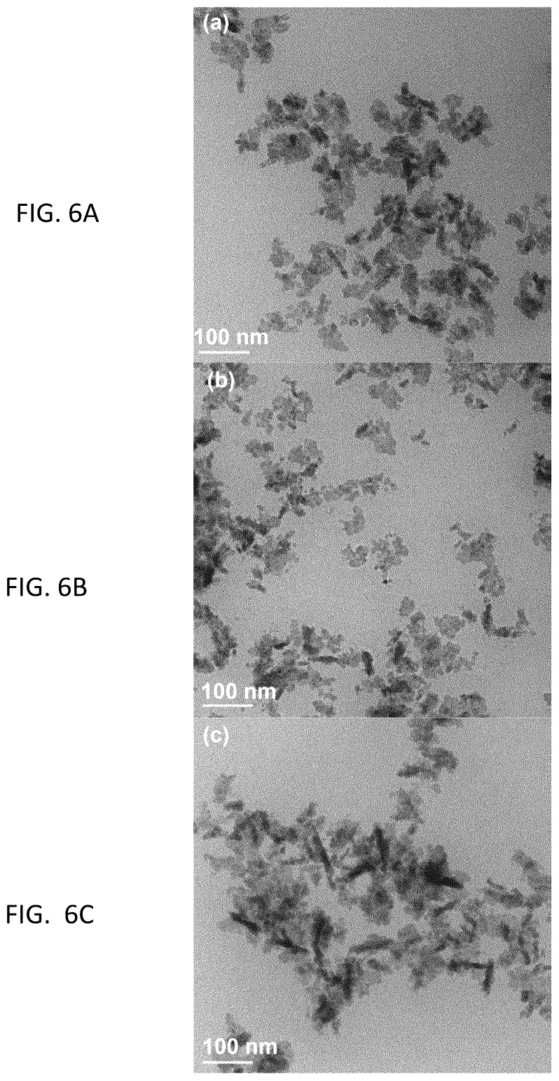

FIGS. 7A-B. UV-vis absorption data with concentration correction to 18 hr NPs or precipitates sample. Absorbance data for the BaZrS3 and initial precipitates at various reaction times are shown in FIG. 7A and FIG. 7B, respectively

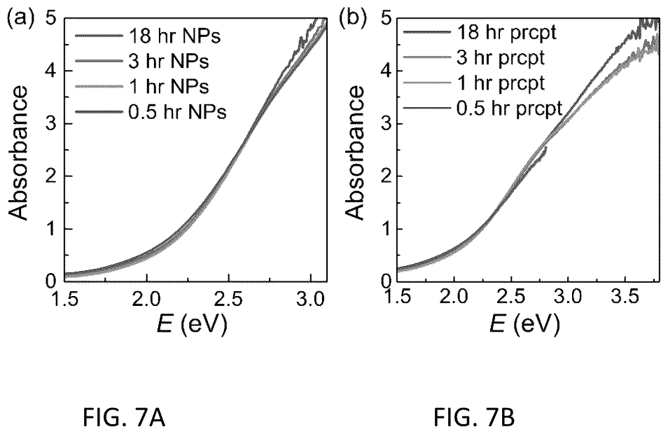

FIG. 8. Tauc plots of nanoparticles (NPs) and initial precipitates (prcpt) from different reaction times with fitting range (2.45, 2.65) eV for NPs and (2.40, 2.60) eV for precipitates.

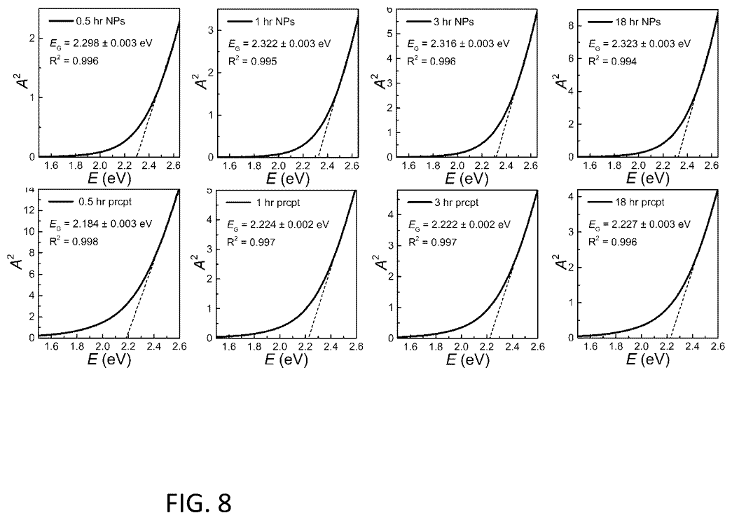

FIGS. 9A-D. TRPL data for the FIG. 9A 0.5 hr, FIG. 9B 1 hr, FIG. 9C 3 hr, and FIG. 9D 18 hr reaction times. The dashed lines area fit of the data to equation (FIG. 7) with the values reported on the figures.

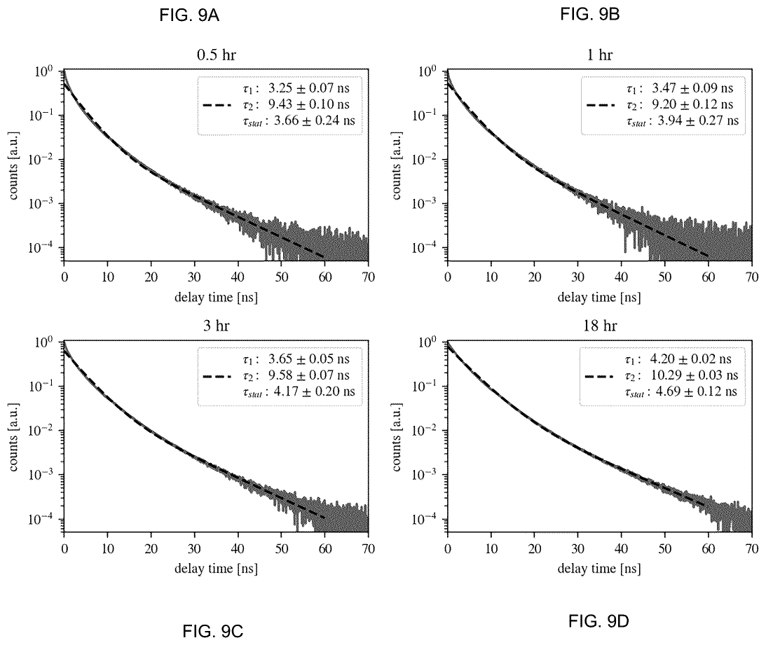

FIG. 10. Bi-exponential fitting residuals in FIG. 9.

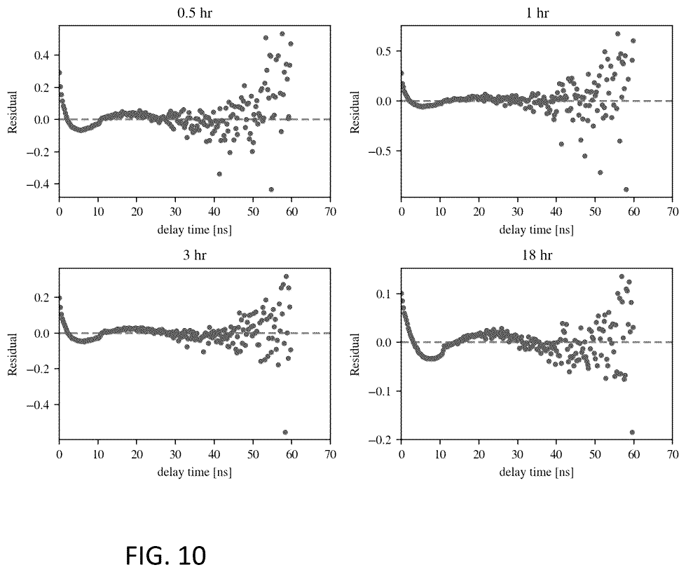

FIGS. 11A-D. TRES plots for the FIG. 11A 0.5 hr, FIG. 11B 1 hr, FIG. 11C 3 hr, and FIG. 11D 18 hr reaction times.

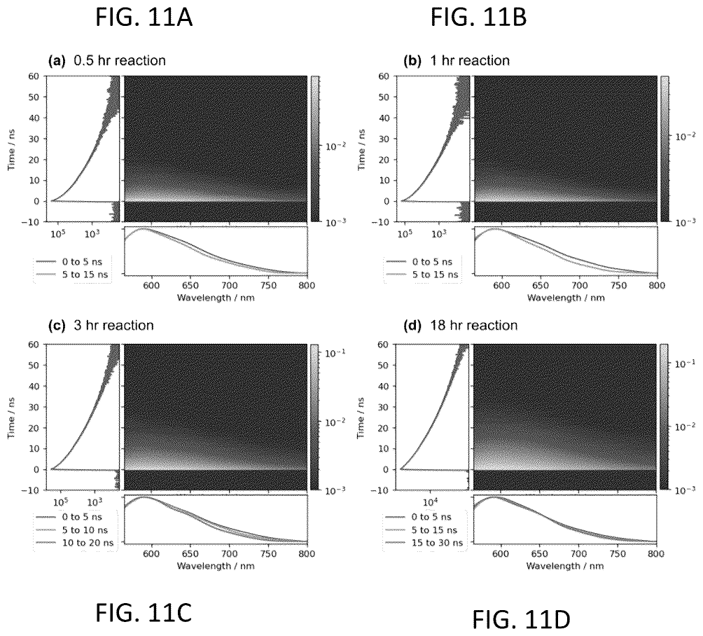

FIGS. 12A-B. XRD patterns of BaZrS3 nanoparticles (NPs) (FIG. 12A) and initial precipitates from different reaction times. Reference data is taken from Clearfield⁴ for BaZrS3 (FIG. 12B).

FIG. 13 Raman spectrum of BaZrS3 nanoparticles from the 18 hr reaction.

FIGS. 14A-C. Bright-field TEM image of initial precipitate from the 18 hr reaction (FIG. 14A), BaZrS3 nanoparticles from the 3 hr reaction (FIG. 14B) and initial precipitate from the 3 hr reaction (FIG. 14C).

FIGS. 15 A-B. UV-vis absorption data with concentration correction to 18 hr NPs (FIG. 15A) or precipitates sample (FIG. 15B).

FIG. 16 Tauc plots of nanoparticles (NPs) and initial precipitates (prcpt) from different reaction times with fitting range (2.45, 2.65) eV for NPs and (2.40, 2.60) eV for precipitates.

### DETAILED DESCRIPTION

### Introduction and Definitions

Various embodiments may be understood more readily by reference to the following detailed description. Unless defined otherwise, all technical and scientific terms used herein have the same meaning as commonly understood by one of ordinary skill in the art to which this disclosure belongs.

As used herein, the term “standard temperature and pressure” generally refers to 25° C. and 1 atmosphere. Standard temperature and pressure may also be referred to as “ambient conditions.” Unless indicated otherwise, parts are by weight, temperature is in ° C., and pressure is at or near atmospheric. The terms “elevated temperatures” or “high-temperatures” generally refer to temperatures of at least 100° C.

The term “mol percent” or “mole percent” generally refers to the percentage that the moles of a particular component are of the total moles that are in a mixture. The sum of the mole fractions for each component in a solution is equal to 1.

Unless otherwise defined, all technical and scientific terms used herein are intended to have the same meaning as commonly understood in the art to which this invention pertains and at the time of its filing. Although various methods and materials similar or equivalent to those described herein can be used in the practice or testing of the present invention, suitable methods and materials are described below. However, the skilled should understand that the methods and materials used and described are examples and may not be the only ones suitable for use in the invention. Moreover, it should also be understood that as measurements are subject to inherent variability, any temperature, weight, volume, time interval, pH, salinity, molarity or molality, range, concentration and any other measurements, quantities or numerical expressions given herein are intended to be approximate and not exact or critical figures unless expressly stated to the contrary. Hence, where appropriate to the invention and as understood by those of skill in the art, it is proper to describe the various aspects of the invention using approximate or relative terms and terms of degree commonly employed in patent applications, such as: so dimensioned, about, approximately, substantially, essentially, consisting essentially of, comprising, and effective amount.

It is to be understood that this disclosure is not limited to particular embodiments described, as such may, of course, vary. It is also to be understood that the terminology used herein is for the purpose of describing particular embodiments only, and is not intended to be limiting, since the scope of the present disclosure will be limited only by the appended claims.

All numeric values are herein assumed to be modified by the term “about,” whether or not explicitly indicated. The term “about” generally refers to a range of numbers that one of skill in the art would consider equivalent to the recited value (i.e., having the same function or result). In many instances, the term “about” may include numbers that are rounded to the nearest significant figure. In specific embodiments, the term “about” means plus or minus 20 percent of the recited value, so that, for example, “about 0.125” means 0.125±0.025, and “about 1.0” means 1.0±0.2. Notwithstanding that the numerical ranges and parameters setting forth the broad scope of the invention are approximations, the numerical values set forth in specific non-limiting examples are reported as precisely as possible. Any numerical value, however, inherently contains certain errors necessarily resulting from the standard deviation found in their respective testing measurements at the time of this writing. Furthermore, unless otherwise clear from the context, a numerical value presented herein has an implied precision given by the least significant digit. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 4.

Where a range of values is provided, it is understood that each intervening value, to the tenth of the unit of the lower limit (unless the context clearly dictates otherwise), between the upper and lower limit of that range, and any other stated or intervening value in that stated range, is encompassed within the disclosure. The upper and lower limits of these smaller ranges may independently be included in the smaller ranges and are also encompassed within the disclosure, subject to any specifically excluded limit in the stated range. Where the stated range includes one or both of the limits, ranges excluding either or both of those included limits are also included in the disclosure.

All publications and patents cited in this specification or Appendix Aare herein incorporated by reference as if each individual publication or patent were specifically and individually indicated to be incorporated by reference and are incorporated herein by reference to disclose and describe the methods and/or materials in connection with which the publications are cited. The citation of any publication is for its disclosure prior to the filing date and should not be construed as an admission that the present disclosure is not entitled to antedate such publication by prior disclosure. Further, the dates of publication provided could be different from the actual publication dates that may need to be independently confirmed.

Unless otherwise indicated, the present disclosure is not limited to particular materials, reagents, reaction materials, manufacturing processes, or the like, as such can vary. It is also to be understood that the terminology used herein is for purposes of describing particular embodiments only and is not intended to be limiting. It is also possible in the present disclosure that steps can be executed in different sequence where this is logically possible.

It must be noted that, as used in the specification and the appended claims, the singular forms “a,” “an,” and “the” include plural referents unless the context clearly dictates otherwise. Thus, for example, reference to “a support” includes a plurality of supports. In this specification and in the claims that follow, reference will be made to a number of terms that shall be defined to have the following meanings unless a contrary intention is apparent.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

The examples and embodiments described herein are for illustrative purposes only and that various modifications or changes in light thereof will be suggested to persons skilled in the art and are to be included within the spirit and purview of this application. Many variations and modifications may be made to the above-described embodiment(s) of the disclosure without departing substantially from the spirit and principles of the disclosure. All such modifications and variations are intended to be included herein within the scope of this disclosure.

### Detailed Description of Embodiments

According to certain embodiments, provided is a method for producing perovskite nanoparticles. In a specific example, the method involves:
a) Forming ZrDEtDTC and BaDBuDTC as follows:

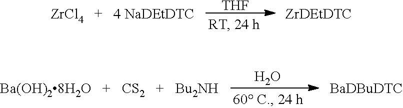

and
b) Forming BAZrS3 nanoparticles as follows:

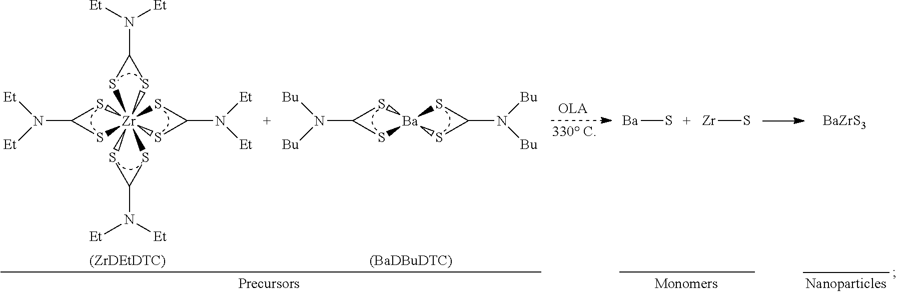

wherein the reaction conditions are optional. In a specific embodiment, step b) occurs at 300-400 degrees C., or about 330 degrees C. Also, in certain embodiments, the nanoparticles may range from about 10-20 nm in size. In a specific embodiment, the nanoparticles are comprised of 3-5 nm crystalline domains.

According other embodiments, provided are perovskite nanoparticles produced by the methods described herein. In a specific example, the nanoparticles are about 10-20 nm in size. Also, the nanoparticles described herein may possess photoluminescence decay times as high as 4.7 ns.

In yet further embodiments, disclosed is an optoelectronic device comprising perovskite nanoparticles, wherein the perovskite nanoparticles comprise a photoluminescence decay time as high as 4.7 ns. In a specific example, the optoelectronic device is a photovoltaic. In specific examples, the photovoltaic device includes, but is not limited to, a photodiode, phototransistor, photmultiplier, optoisolator or integrated optical circuit.

### Examples

### Example 1: Low-Temperature, Solution-Based Synthesis of Luminescent Chalcogenide Perovskite BaZrS3 Nanoparticles

Chalcogenide perovskites—eponymously named for containing S, Se, or Te as the anion rather than a halide—are an emerging frontier in Pb-free, inorganic perovskites with high stability. Promising optoelectronic properties have been identified for this material family, primarily from theory, including band gap values relevant for photovoltaics, a tolerance to deep defects, strong dielectric screening for generating free carriers with a long lifetime, favorable phonon properties for high-performance thermoelectrics, and desirable (isotropic) electron mobility for efficient charge transport.¹⁻⁸ Furthermore, a high density of chalcogenide p-states in the valence band maximum results in an extraordinarily high absorption coefficient, exceeding those of other solar technologies.^{9,10} Importantly, increased covalent bonding in the crystal lattice relative to that in halide perovskites results in enhanced structural stability.^{6,11-14}

However, the cost of structural stability for chalcogenide perovskites can be associated with a high crystallization energy barrier for these materials. While chalcogenide perovskites have been sparsely reported for ca. 60 years, the majority of reported syntheses require temperatures around 1000° C. and reaction times on the order of days to weeks (generally using solid-state reaction techniques).^{1,5} Such conditions limit the possibility of using most tunable synthesis techniques to control material growth and preclude the majority of substrates commonly used for electronics. The majority of chalcogenide perovskite syntheses also report powders and pellets, which are unrealistic for realizing the properties of chalcogenide perovskites in functional applications. The present high temperature requirements, long synthesis times, and lack of thin-film syntheses are significant barriers to research in chalcogenide perovskites, and the demonstration of solution-based synthesis has been identified as a key goal in chalcogenide perovskite research.^{5,6}

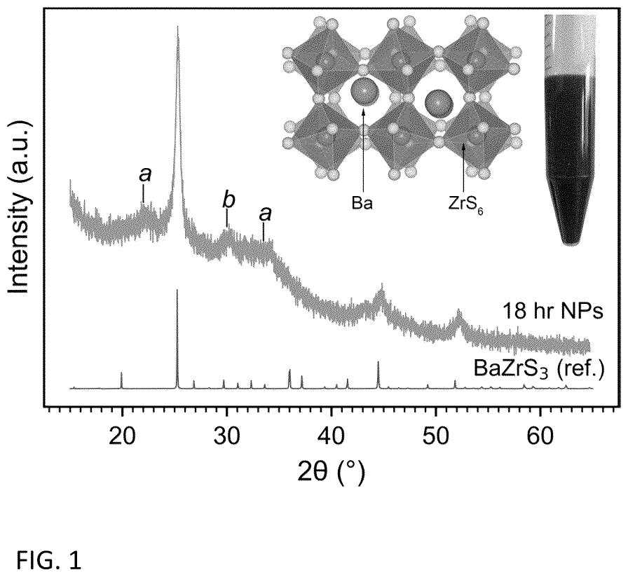

In this Example, presented is the first bottom-up colloidal synthesis of chalcogenide perovskite nanoparticles, demon-strated here for BaZrS3, which is known to crystallize in the desired distorted perovskite crystal structure, shown in the inset of FIG. 1. The nanoparticles were synthesized by a thermal decomposition mechanism via the heat-up synthesis technique.¹⁵ First, reactive single-source precursors were synthesized for Ba and Zr (described below) as barium dibutyldithiocarbamate (BaDBuDTC) and zirconium diethyldithiocarbamate (ZrDEtDTC), respectively. The precursors (0.244 mmol, respectively) were loaded into a homemade reactor with 1 mL of dry oleylamine (OLA) as the solvent/ligand. The mixture was heated (ca. 5° C./min) to the reaction temperature of 330° C. BaDBuDTC is fully soluble at ca. 80° C., while ZrDEtDTC is fully soluble at ca. 120° C., at which point a clear solution (yellow tint) is formed. Shortly after complete dissolution, the mixture changed to a turbid pale yellow, then orange, and finally dark red over the course of heating, with gaseous byproduct generated during the reaction. Due to the extreme oxophilicity of Zr, the precursors were handled in a glovebox, OLA was dried and degassed prior to use, and the synthesis utilized air-free techniques (Schlenk line) under ultra-high-purity Ar. A series of identical reactions were carried out for various reaction times (0.5, 1, 3, and 18 h). Following the reaction, the product was first dispersed in toluene and isolated by centrifugation (5000 rpm, 5 min). An initial precipitate phase (described below) which does not form a stable dispersion in organic solvent was first separated. The remaining supernatant, containing the target BaZrS3 nano-particles, was diluted with ethanol as an anti-solvent and recovered via a second centrifugation (10 000 rpm, 5 min). These particles can be kept as a stable dispersion (nanoparticle ink) over weeks without settling, shown in toluene in the inset of FIG. 1.

To achieve a low-temperature synthesis, a sufficiently reactive precursor is required. Here metal-dithiocarbamate (DTC)-based precursors were used due to their favorable solubility in organic solvent and low-temperature thermal decomposition (below 300° C.); the decomposition temperature is also tunable based on the choice of organic functional groups (dibutyl and diethyl used here for Ba and Zr, respectively). Individually, these precursors can be used for the synthesis of BaS and ZrS₂. An additional sulfur source is not required for the reactions, as metal-sulfide monomers are directly generated from the thermal decomposition of the metal-DTC. We previously reported the use of metal-DTC precursors for the synthesis of BaSnS₃ (non-perovskite needlelike phase) as well as SnS, SnS₂, and ZrS₂,¹⁷⁻¹⁹ and they have also recently been reported for the synthesis of BaTiS₃ (nonperovskite hexagonal phase).²⁰ In general, metal-DTCs are prevalent in the synthesis of metal sulfides and have been reported for the majority of metal cations due to their favorable reactivity, single-source nature for metals and sulfur, and relative ease of synthesis. Importantly, the metal-DTC precursors are free of oxygen (e.g., compared to acetylacetonates and ethers), to prevent oxidation at the reaction temperature. Additionally, common chloride precursors (ZrCl₄ and BaCl₂) are incompatible with this reaction due to the insolubility of BaCl₂ in organic solvents.

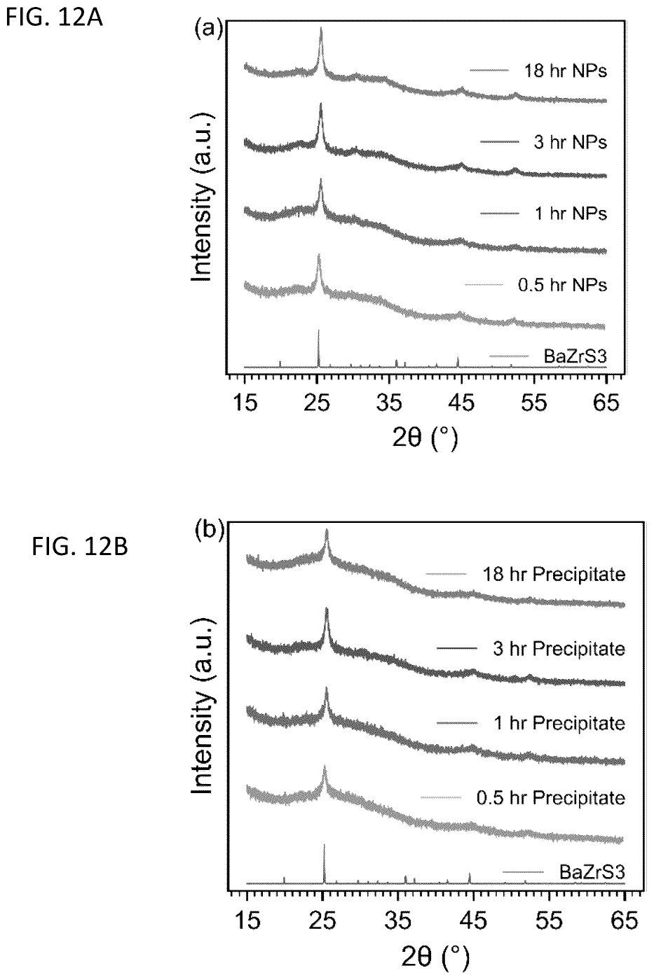

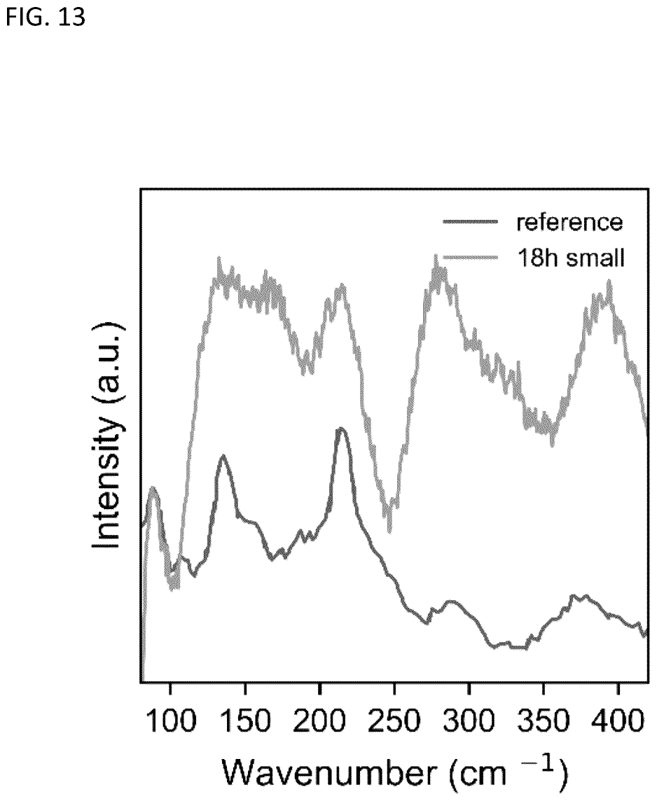

Powder X-ray diffraction (XRD) data of the nanoparticles from the longest reaction time (18 h) are shown in FIG. 1. The main peaks that can be resolved at 25.2, 44.5, and 52.8° 2θ are in good agreement with the reference for BaZrS3 in the orthorhombic (Pnma) distorted perovskite structure.¹⁶ The XRD patterns show clear texturing of the sample, dominated by the (121) or (002) reflections which overlap at 25.2° 2θ; accordingly, parallel reflections from (242) or (004) at 52.8° 2θ also appear with a relatively increased intensity. Such texturing can be expected from anisotropic nanoparticles which can orient in non-random directions during sample preparation.²¹ In addition, small impurity peaks labeled a and b are found. The two peaks labeled a were also reported by Comparotto et al.⁸ and may be associated with a Zr-rich region, though the origin could not be identified. The peak labeled b is a good match for ZrO₂ or BaZrO₃; ZrO₂ may form from trace oxygen during synthesis, while BaZrO₃ would be a result of minor post-synthesis oxidation of the nanoparticles. XRD patterns for the shorter reaction times (0.5, 1, and 3 h) are virtually identical (see FIG. 12). The phase of the BaZrS3 nanoparticles was also verified by Raman spectroscopy (see FIG. 13).

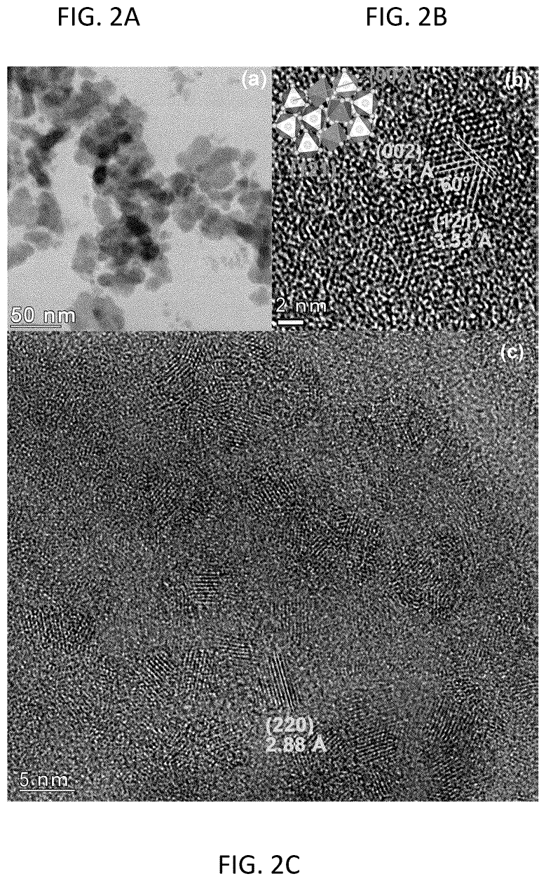

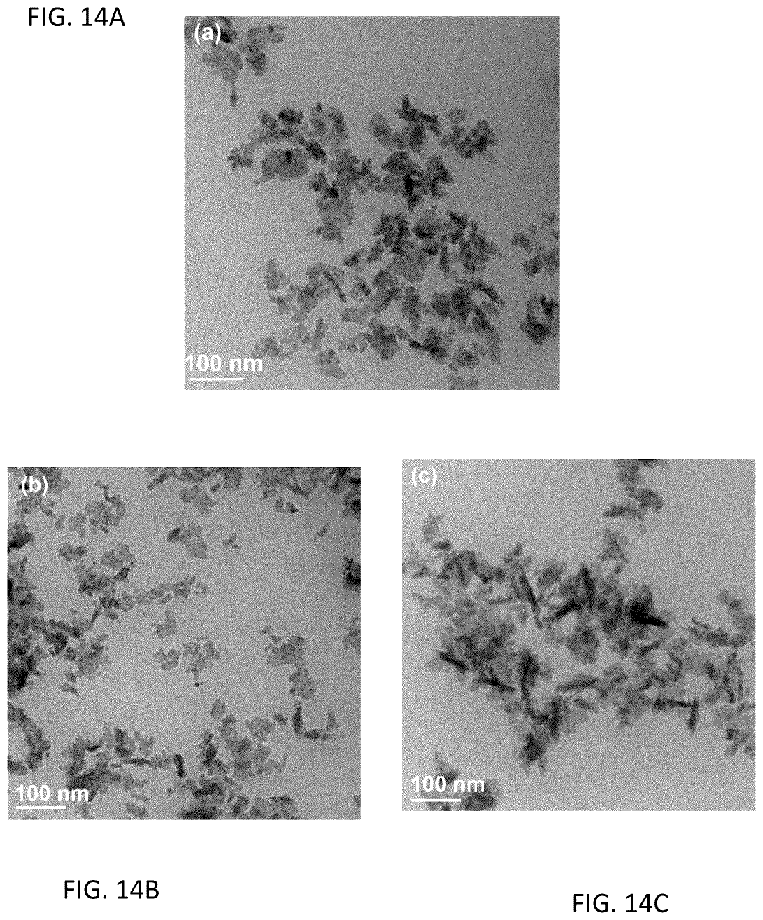

A bright-field transmission electron microscopy (TEM) image of nanoparticles from the 18 h reaction is shown in FIG. 2a, illustrating a heterogeneous particle size around 10-20 nm. High-resolution TEM (HRTEM) of individual particles indicates that multiple smaller crystalline domains (3-5 nm) exist within a larger particle, illustrated in FIG. 2c; lattice fringes with a measured d-spacing of 2.88 A corresponding to the {220} planes are shown. Interestingly, the randomly oriented small domains in FIG. 2c predominately show the same fringes of the {220} planes, suggesting preferential growth inside individual nanoparticles. FIG. 2b shows another HRTEM image showing different fringes with a measured d-spacing of 3.51 and 3.53 A, corresponding to the {002} and {121} planes, respectively; the expected dihedral angle of 60.0° is indicated. The inset of FIG. 2b illustrates the structure of BaZrS3 with the (002) and (121) planes indicated. Additional TEM images can be found in FIG. 14 as well as for a shorter reaction time (3 h), though a similar morphology and particle size are found, in agreement with the similar XRD.

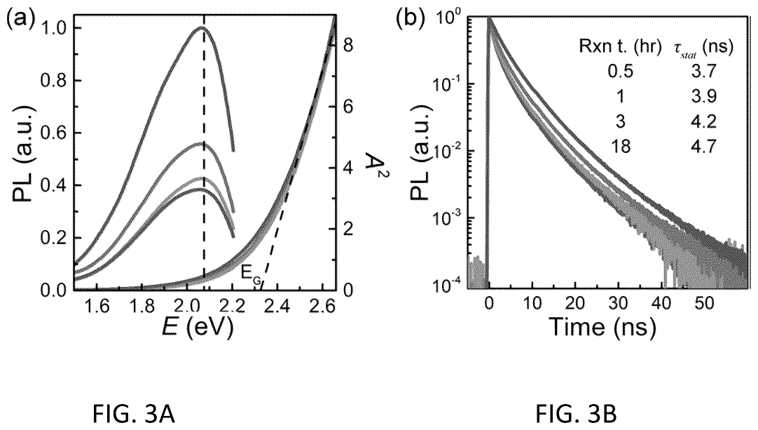

Optoelectronic properties of the synthesized BaZrS3 were measured with UV-vis and photoluminescence (PL, 532 nm excitation) for the nanoparticles dispersed in toluene. Absorbance data A as a Tauc plot (A² vs E, for crystalline semiconductors)²² is shown for the four reaction times in FIG. 3a in comparison to the steady-state PL spectra; PL and absorbance data are normalized by their relative sample concentration for comparison. Data for all reaction times yield virtually identical absorbance and emission spectra, with a band gap of ca. 2.3 eV and a PL peak position at 2.08 eV. A shoulder can be observed in the PL spectra near 1.9 eV. Both the band gap and PL peak position are larger than those reported for bulk BaZrS3 in the literature,¹ which may be attributed to quantum confinement effects originating from the small crystalline domains. Samples with equivalent absorbance show an increase in the steady state PL yield with increasing reaction time. In agreement, time-resolved PL (TRPL, 532 nm excitation at 9.74 MHz) similarly shows an increase in the PL decay time with increasing reaction time, shown in FIG. 3b. As the TRPL is sampled over numerous BaZrS3 particles or domains, we report a statistical lifetime τ stat from a biexponential fit to the PL decay²³ (see SI), which yields 3.7±0.2, 3.9±0.3, 4.2±0.2, and 4.7±0.1 ns for the increasing reactions times, respectively. For comparison, TRPL decay lifetimes have not been previously reported for BaZrS3, though a <7 ns lifetime has been approximated from the steady-state PL yield of a thin film.^{1,24} While TRPL in FIG. 3b is an integral over the emission spectrum, time-resolved emission spectra shows that the PL spectra decays uniformly in time.

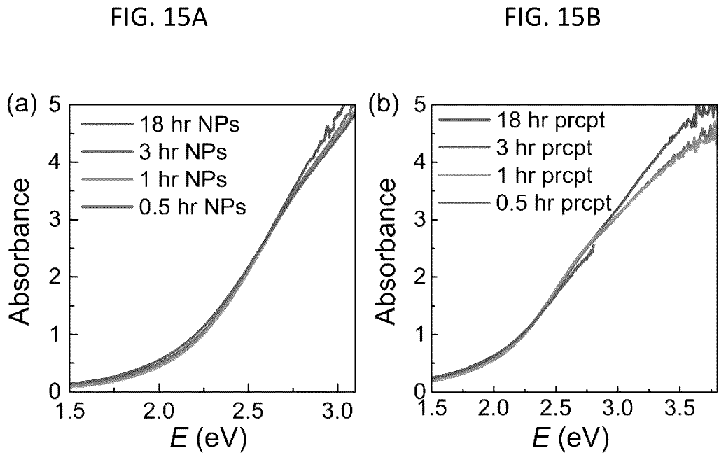

Based on the preceding results, and without being bound to any particular theory, it is believed that the increased reaction time aids in annealing defects in the BaZrS3 nanoparticles. It is believed that the relatively low reaction temperature is also associated with the observed small intraparticle domains, which may uniquely contribute to the observed optoelectronic behavior. Initially, the 0.5 h reaction contains an estimated 50/50 mass ratio of the initial precipitate phase to the target BaZrS3 nanoparticles described herein; this decreases to approximately 20/80 for the 18 h reaction. This initial precipitate phase has similar XRD, TEM, and appearance to the target nanoparticles; however, the instability of the initial precipitates as a dispersion suggests their precipitation is a result of surface properties rather than particle size. Also, a relatively smaller band gap and no PL emission can be detected for this initial precipitate phase (see FIG. 15). It is believed that this initial precipitate is an intermediate or highly defective BaZrS3 phase which transitions to the target nanoparticles with increasing reaction time.

In summary, reported is a low-temperature (330° C.), solution-based synthesis for chalcogenide perovskite BaZrS3 nanoparticles. The nanoparticles demonstrate promising optoelectronic properties based on their PL/TRPL, which is encouraging for photovoltaic applications. This result opens the door to using nanoparticle inks 25-27 of chalcogenide perovskite for the realistic fabrication of thin films and devices.

### I. Chemicals

Zirconium chloride anhydrous (ZrCl₄, 98%, Sigma, CAS: 10026-11-6), barium hydroxide octahydrate (Ba(OH)₂·8H2O, 98%, Sigma, CAS: 12230-71-6), sodium diethyldithiocarbamate trihydrate (NaDEtDTC-3H₂O, 99%, Sigma, CAS: 20624-25-3), dibutylamine (Bu₂NH, 99.5%, Sigma, CAS: 111-92-2), oleylamine (OLA, 70%, Sigma, CAS: 112-90-3) were purchased from Sigma-Aldrich. Carbon disulfide (CS2, 99.9%, Fisher, CAS: 75-15-0), tetrahydrofuran (THF, 99.9%, Fisher, CAS: 109-99-9), toluene (99.8%, Fisher, CAS: 108-88-3), calcium hydride (CaH2, 92%, Fisher, CAS: 7789-78-8) were purchased from Fisher.

OLA was dried by fluxing with CaH₂ under vacuum at 200° C. for 2 hr, followed by centrifugation and filtration to remove CaH₂, OLA was then degassed by freeze-pump-thaw 3 times and stored in a glovebox. THF was dehydrated with 3 Å molecular sieves. Toluene was dried with 3 Å molecular sieves. All materials were used as received if pretreatment is not otherwise described.

### II. Synthesis

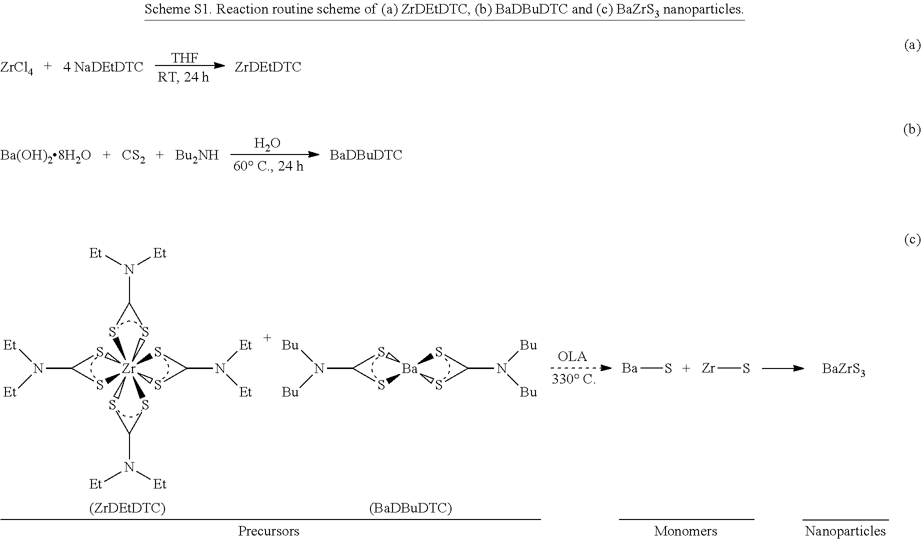

Scheme S1 shows the overall procedure for BaZrS3 NPs synthesis. ZrDEtDTC and BaDBuDTC were first synthesized as Scheme S1 (a) and (b), respectively. These metal-DTC precursors were then used for nanoparticle synthesis (c), followed by separation with centrifugation and anti-solvent precipitation/washing. The nanoparticles were formed via thermal decomposition of the metal-DTC precursors into monomers following the heat-up synthesis mechanism.¹ We hypothesize the formation of Ba—S and Zr—S monomers via the thermal decomposition of the metal-DTCs, with subsequent nucleation of the ternary phase. The OLA solvent, potentially unreacted precursors, and any byproducts (e.g., ammonium salts) are readily separated from the target BaZrS3 nanoparticles during nanoparticle washing.

### 1. ZrDEtDTC Synthesis

A modified procedure was used for ZrDEtDTC synthesis following Behrle et al.² In a glovebox, anhydrous NaDEtDTC (32 mmol, prepared by dehydration of 10 g of NaDEtDTC-3H2O in a vacuum oven at 100° C. for 3 hr) and anhydrous ZrCl₄ (8 mmol) were first loaded into a 500 mL one-neck round-bottom flask, assembled with an addition funnel capped with a rubber septum. In the fume hood, dry THE (60 mL) was injected into the funnel with a syringe and filter. THE was added to the powder mixture drop-wise over an ice water bath. The mixture was then stirred for 24 hrs with ice bath slowly warming up to room temperature. The white mixture turned yellow over the course of the reaction. THE was removed via evaporation under vacuum. Excess toluene was added to the flask to extract ZrDEtDTC. The extraction solution was filtered through a Celite bed without exposing to air. The filtered extraction was then distilled under vacuum with a warm water bath (50° C.) to remove toluene. The yellowish product was collected and dried in a vacuum oven at 50° C. for 24 hrs.

### 2. BaDBuDTC Synthesis

The BaDBuDTC synthesis method was adopted and modified from Olin el al.³ Dibutylamine (100 mmol) was first dissolved in water (20 mL) in a 125 mL Erlenmeyer flask. Ba(OH)₂·8H2O (50 mmol) was then dispersed in the mixture. CS2 (100 mmol) was dropped in with constant stirring over an ice water bath. After addition of CS2, the mixture was heated with a warm water bath at 60° C. for 24 hr. The solid was first centrifuged down, followed by drying in a vacuum oven at 60° C. for 24 hr. The solid was then extracted by toluene. The extraction solvent was removed by evaporation to give a white powder. The product was dried in a vacuum oven at 60° C. for another 24 hr.

### 3. BaZrS3 Nanoparticle Synthesis

In the glovebox, BaDBuDTC (0.244 mmol) and ZrDEtDTC (0.244 mmol) were first loaded into a reaction test tube (10 mL), together with a stir bar and 1 mL of dry OLA. The reaction test tube was capped by a valve through a short piece of rubber hose. It was then connected to Schlenk line without exposing to air. Degassing at 80° C. under vacuum and constant stirring for 30 min was applied before the reaction vessel was refilled with ultra-high purity Ar. The mixture was then slowly heated from 80° C. to 330° C. with an overall ramp rate around 5° C./min with a homemade heating mantle. The mixture turned to a clear yellowish solution around 120° C. Then it turned to turbid pale yellow, then orange, and finally dark red. Timing was started when the mantle temperature was 330° C. for 0.5, 1, 3, and 18 hrs, respectively. The product was first washed out of the reaction test tube with toluene and centrifuged at 5000 rpm for 5 min to collect an initial precipitate phase and supernatant containing the target BaZrS3 nanoparticles. Excess ethanol as an antisolvent was added to the supernatant, followed by centrifugation at 10000 rpm for 5 min to collect the target BaZrS3 nanoparticles. Any remaining clear reddish supernatant was discarded. The collected target BaZrS3 nanoparticles and initial precipitate phase were both separately washed three more times with toluene/ethanol (30 mL, 1:5 volume ratio) and centrifugation. The final product was dispersed in toluene, which forms a stable dispersion for (at least) weeks without settling.

### III. Characterization

XRD & Raman: Concentrated dispersions of the BaZrS3 nanoparticles and the initial precipitates in toluene were dropcast onto soda-lime glass; the toluene was removed via vacuum evaporation in a desiccator. XRD was measured on a PANalytical XPert Powder using Cu Kα radiation. Raman spectroscopy was performed on a Horiba LabRAM ARAMIS at 532 nm wavelength excitation with a 100× objective.

TEM: In a glovebox, dilute dispersion of the BaZrS3 nanoparticles and the initial precipitates in toluene were dropped onto copper TEM grids with amorphous carbon support membrane. The samples were further baked (in the glovebox) on a hotplate at 80° C. overnight. TEM was performed on a Talos F200i S/TEM using 200 kV accelerating voltage for both low-resolution and high-resolution TEM images.

UV-Vis: 3 mL of dilute dispersions of the BaZrS3 nanoparticles and the initial precipitates in toluene in a quartz cuvette were prepared for the UV-vis absorption measurements. For each sample, after the first measurement at the initial concentration, 1 mL of the dispersion was replaced with toluene to dilute to 2/3 of its current concentration. Three concentrations were used for each sample. UV-vis was performed on Shimadzu UV-2600 2-beam system in the wavelength range of 300-900 nm, using a toluene filled quartz cuvette as the reference absorption standard.

PL/TRPL: Time-resolved photoluminescence (TRPL) measurements were performed in a custom setup for time correlated single photon counting (using a Picoquant TimeHarp 260 PICO). The same toluene dispersions of BaZrS3 at initial concentration in a quartz cuvette described above for UV-vis were measured (data not included for the initial precipitate phase as no PL is detected). A pulsed supercontinuum laser source (NKT Photonics SuperK Extreme; 5 ps pulse width) tuned to 532 nm wavelength excitation (Spectral bandwidth <2.5 nm) using an NKT Photonics LLTF filter was used for excitation. The laser pulse frequency was tuned to 9.74 MHz. A collimated excitation beam of 8.5 mm diameter with a measured average power of 0.13 mW was used to illuminate the cuvette. Steady-state photoluminescence measurements used a CW 532 excitation laser, also 8.5 mm excitation beam diameter, with an excitation power of 3 mW. Detection for the PL and TRPL used a photomultiplier detector assembly (Picoquant PMA192C) with calibrated response between 230-920 nm. The instrument response time is below <250 ps. The steady-state PL spectra and time-resolved emission spectra used a calibrated Nireos Gemini interferometer to compute the spectrum with a Fourier-transform approach.

### IV. Absorption Data

Optical absorbance A is computed based on the ratio of incident light l0 to the transmitted light l, where

$$A = log 10 ( {I}_{0} / I ) \qquad ( S1 )$$

Data is corrected for any absorbance in the cuvette or solvent with a baseline measurement. The instrument has a dynamic range from A=0.01-5. Absorbance data for the BaZrS3 and initial precipitates at various reaction times are shown in FIGS. 15A and 15B, respectively.

The molar absorption coefficient E is recovered from the absorbance data following the Beer-Lambert law:

$$A = ϵ cl \qquad ( S2 )$$

where c is the sample concentration and l is the path length. Following the Beer-Lambert law, A is proportional to the sample concentration; therefore, the absorption data is normalized to the 18 hr reaction data to account for any variations in the concentration of the absorbing BaZrS3 phase in the samples (normalization does not affect E). To compare, the PL data measured on the same samples is also normalized by the concentration of the 18 hr reaction. The linearity of A and c was verified by measuring A at three concentrations for each sample.

To extract the band gap EG from the absorbance data, a direct band gap absorption model for the absorption coefficient α was applied, following:

$$A ∝ ϵ c ∝ α ∝ {( E - EG )}^{1 / 2} \qquad ( S3 )$$

Equation S3 assumes absorption in a crystalline material with no extrinsic absorption (e.g. defect states, impurities, potential fluctuations) and a parabolic band approximation for the direct transition of interest near the band edge.⁶ The band gap is recovered from a method based on the Tauc plot⁷ from the intercept of a plot of A² vs. E.† A ‘kink’ in the absorbance data can be seen in FIG. 15 due to additional high energy transitions above c. 2.65 eV; therefore, E_{G} was fit to the absorption model of (S3) for the linear region below this value.

[† Tauc plot is originally derived for amorphous semiconductors in the absence of momentum conservation using a constant momentum transition matrix element, resulting in a plot of (A·E)² vs. E.⁷ Similar results are obtained when using A² or (A·E)².]

To gauge the UV-Vis measurement uncertainty, absorbances at the three nominal concentrations were measured for each reaction time, normalized, and averaged, taking the standard deviation across the three measurements as the uncertainty σ_{A}. Uncertainties in A were transformed to uncertainties in A², following σ_{A}²=2Aσ_{A}. Finally, a linear least-squares fit was performed on A₂ with its associated uncertainty σ_{A}² over the energy range E=2.45-2.65 eV for NPs and E=2.40-2.60 eV for precipitates using curve_fit( ) routine in the scipy.optimize Python library.

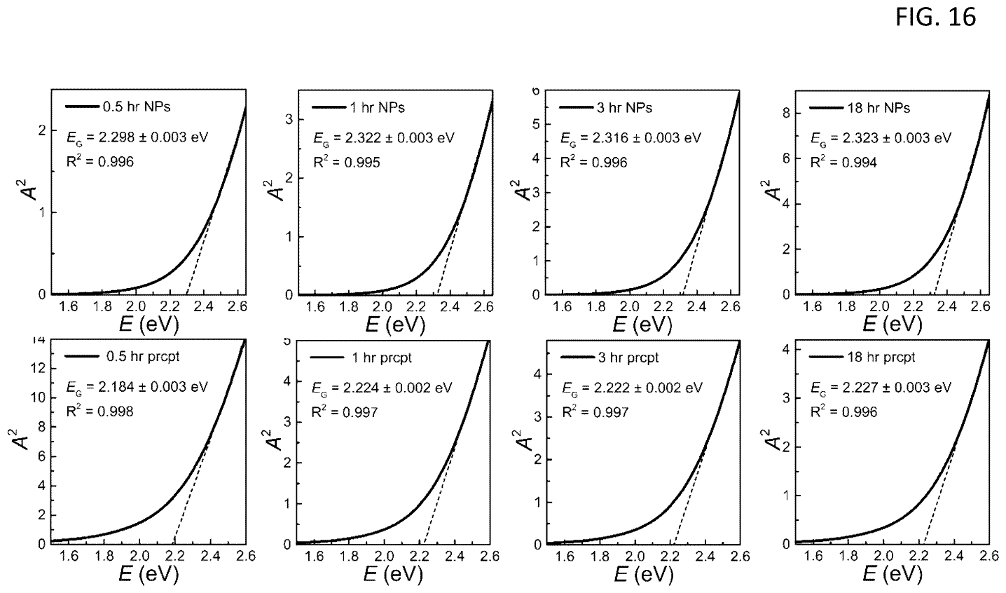

This procedure was repeated for nanoparticles and initial precipitates from each of the four reaction times. The linear fits which extrapolate to the band gap along with their corresponding errors can be found in FIG. 16 for the BaZrS3 nanoparticles and initial precipitates at each reaction time. It should be noted that these errors reflect the EG linear fit and measurement error, though not the error due to the choice of energy range for fitting or validity of the absorption model (a common issue from Tauc plot analysis).

### V. Optical Measurement Data

### PL/TRPL:

Analytical fitting of TRPL decays to extract a recombination lifetime from the PL decay time is typically based on simplified 1 D transport equations for large crystalline domains.⁸ Due to the nanocrystalline nature of our BaZrS3 sample (along with the inherent sampling over numerous particles and domains) we have provided a PL decay time based on statistical lifetime τstat from a bi-exponential fit to the data, as similarly reported by Hages et al.⁹ The PL decays were fit with the following bi-exponential function:

$$PL ( t ) = {C}_{1} {e}^{\frac{- t}{{τ}_{1}}} + {C}_{2} {e}^{\frac{- t}{{τ}_{2}}} \qquad ( S4 )$$

where the statistical lifetime was computed as:

$${τ}_{stat} = \frac{{C}_{1} {τ}_{1} + {C}_{2} {τ}_{2}}{{C}_{1} + {C}_{2}} \qquad ( S5 )$$

TRPL data along with the fits (dashed lines) can be seen in Figure S6 for each reaction time. Fit residuals can be found in Figure S7. We correlate τstat to the recombination lifetime, as the increasing TRPL decay time is in agreement with the measured increase in steady-state PL yield. However, τstat should be taken as a rough gauge for recombination rather than a strict value for the recombination lifetime due to the somewhat complex decay behavior observed (e.g. bi-exponential) which is not easily fit to 1 D carrier transport approximations to extract the recombination parameters.

### Time-Resolved Emission Spectra (TRES):

The following TRES plots (Figure S8) show the time-resolved PL decay (ordinate), where the PL spectrum at each time point (abscissa) is computed based on a Fourier-transform of the time-resolved PL data measured via an interferometer. The PL spectrum is found to remain uniform throughout the decay. The marginalized decay plot (left) is integrated over the entire spectrum while the marginalized normalized PL spectrums (bottom) are shown for integration over different time regions.

### REFERENCES

(1) van Embden, J.; Chesman, A. S. R.; Jasieniak, J. J. The Heat-Up Synthesis of Colloidal Nanocrystals. Chem. Mater. 2015, 27 (7), 2246-2285.
(2) Behrle, A. C.; Myers, A. J.; Kerridge, A.; Walensky, J. R. Coordination Chemistry and OTAIM Analysis of Homoleptic Dithiocarbamate Complexes, M(S2CNiPr2)4 (M=Ti, Zr, Hf, Th, U, Np). Inorg. Chem. 2018, 57 (17), 10518-10524.
(3) Olin, J. F.; Deger, T. E. Process for Producing Metal Salts of Substituted Dithiocarbamic Acids. U.S. Pat. No. 2,492,314A, Dec. 27, 1949.
(4) Clearfield, A. The Synthesis and Crystal Structures of Some Alkaline Earth Titanium and Zirconium Sulfides. Acta Crystallogr. 1963, 16 (2), 135-142.
(5) Wei, X.; Hui, H.; Zhao, C.; Deng, C.; Han, M.; Yu, Z.; Sheng, A.; Roy, P.; Chen, A.; Lin, J.; Watson, D. F.; Sun, Y.-Y. Y.; Thomay, T.; Yang, S.; Jia, Q.; Zhang, S.; Zeng, H. Realization of BaZrS3 Chalcogenide Perovskite Thin Films for Optoelectronics. Nano Energy 2020, 68 (November 2019), 104317.
(6) Zanatta, A. R. Revisiting the Optical Bandgap of Semiconductors and the Proposal of a Unified Methodology to Its Determination. Sci. Rep. 2019, 9 (1), 11225. https://doi.org/10.1038/s41598-019-47670-y.
(7) Tauc, J.; Grigorovici, R.; Vancu, A. Optical Properties and Electronic Structure of Amorphous Germanium. Phys. Status Solidi B 1966, 15 (2), 627-637.
(8) Hages, C. J., Levcenco, S., Miskin, C. K., Alsmeier, J. H., Abou-Ras, D., Wilks, R. C., Bär, M., Unold, T. & Agrawal, R. Improved performance of Ge-alloyed CZTGeSSe thin-film solar cells through control of elemental losses. Progress in Photovoltaics: Research and Applications. 2015, 23, 376-384.
(9) Hages, C. J., Redinger, A., Levcenko, S., Hempel, H., Koeper, M. J., Agrawal, R., Greiner, D., Kaufmann, C. A. & Unold, T. Identifying the Real Minority Carrier Lifetime in Nonideal Semiconductors: A Case Study of Kesterite Materials. Advanced Energy Materials. 2017, 7, 1700167.

What is claimed is:

1. A method for producing perovskite nanoparticles, the method comprising:
a) Forming ZrDEtDTC and BaDBuDTC as follows: 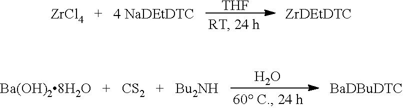
and
b) Forming BAZrS3 nanoparticles as follows: 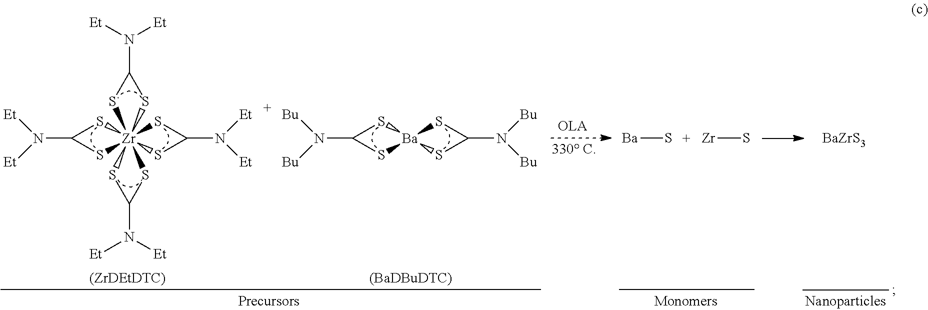
wherein the reaction conditions set forth in steps a) and b) are optional.

2. The method according to claim 1, wherein step b) occurs at 300-400 degrees C., or about 330 degrees C.

3. The method of claim 1, wherein the nanoparticles are about 10-20 nm in size.

4. The method of claim 3, wherein the nanoparticles are comprised of 3-5 nm crystalline domains.

5. Nanoparticles produced by the method of claim 1.

6. The nanoparticles of claim 5, wherein the nanoparticles are about 10-20 nm in size.

7. The nanoparticles of claim 5, wherein the nanoparticles comprise a photoluminescence decay times as high as 4.7 ns.

8. An optoelectronic device comprising perovskite nanoparticles comprising a photoluminescence decay time as high as 4.7 ns.

9. An optoelectronic device comprising perovskite nanoparticles of claim 5.

10. The optoelectronic device of claim 9, wherein the optoelectronic device is a photovoltaic.
